(19) United States
(12) Patent Application Publication
(10) Pub. No.: US 2026/0047312 A1
(43) Pub. Date: Feb. 12, 2026

(54) Display Device

(71) Applicant: LG Display Co., Ltd., Seoul (KR)

(72) Inventor: WonTae Kim, Paju-si (KR)

(21) Appl. No.: 19/077,402

(22) Filed: Mar. 12, 2025

(30) Foreign Application Priority Data
Aug. 12, 2024 (KR) 10-2024-0107688

(51) Int. Cl. H10K 59/80; H10K 59/95; H10K 102/00

(52) U.S. Cl. CPC H10K 59/80; H10K 59/95; H10K 2102/311

(57) ABSTRACT

A display device is provided, a COF film that is electrically connected to the display panel and having a bent shape, and a protection part surrounding the COF film and having a bent shape, and wherein one side of the COF film is connected to the display panel, and the other side of the COF film is disposed on a rear surface of the support member.

### CROSS-REFERENCE TO RELATED APPLICATION

This application claims the benefit of the Republic of Korea Patent Application No. 10-2024-0107688 filed on Aug. 12, 2024, which is hereby incorporated by reference in its entirety.

### BACKGROUND

### Field of Technology

The present disclosure relates to a display device.

### Description of the Related Art

As the information society develops, various demands for display devices that display images are increasing. Accordingly, various types of display devices such as a liquid crystal display apparatus and an organic light emitting diode display apparatus are being utilized.

Among the display devices, the organic light emitting display device is a self-luminous type, has superior viewing angles and contrast ratios compared to the liquid crystal display, is lightweight and thin because a separate backlight is not required, and power consumption is advantageous. In addition, organic light emitting display devices have advantages of low voltage driving, fast response speed, and low manufacturing cost.

Recently, the organic light emitting display device equipped with a flexible plastic substrate has been manufactured. Specifically, polyimide may be coated on a support substrate formed of glass. After that, device such as thin film transistors and organic light emitting diodes may be manufactured on the polyimide, and a Chip on Film (COF) may be attached to a pad part. And, by a process of separating the support substrate from the polyimide, the organic light emitting display device equipped with the flexible plastic substrate may be manufactured.

### SUMMARY

The present disclosure has been made in view of the above problems and it is an embodiment of the present disclosure to provide a display device that prevents or at least reduces cracks caused by external factors from damaging a bending part of the COF film and includes a stably equipped bending part.

In addition to, the present disclosure has been made in view of the above problems and it is an embodiment of the present disclosure to provide a display device with a solid coupling structure and slimming and narrow bezel implemented by improving a fixing force between the components of the display device.

In accordance with an embodiment of the present disclosure, the above and other technical effects can be accomplished by the provision of a display device comprising a display panel, a backplate supporting the display panel, a support member supporting the back plate, a COF film that is electrically connected to the display panel and having a bent shape, a protection part surrounding the COF film and having a bent shape, and an adhesive member disposed between the COF film and the protection part, wherein one side of the COF film is connected to the display panel, and the other side of the COF film is disposed on a rear surface of the support member.

In addition to, the present disclosure prevents or at least reduces a COF film from being damaged by cracks generated by external factors by forming a protection part that surrounds the COF film and bends.

In addition to, a protection part according to the present disclosure includes a material having a high elongation, and thus may fix a COF film while being flexibly bent. Accordingly, the COF film may be bent with only a minimum curvature, and a slimming and a narrow bezel may be implemented in a display device.

In addition to, a protection part according to the present disclosure includes a bending part in which various patterns are formed, thereby implementing smooth bending.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a display device according to an embodiment of the present disclosure.

FIG. 2 is a block diagram of a display device according to an embodiment of the present disclosure.

FIG. 3 is a circuit diagram illustrating a circuit configuration of a subpixel according to an embodiment of the present disclosure.

FIG. 4 is a circuit diagram illustrating a circuit configuration of a subpixel according to another embodiment of the present disclosure.

FIG. 5 is a cross-sectional view illustrating a sub-pixel of a display device according to an embodiment of the present disclosure.

FIG. 6 is a cross-sectional view of a display device according to an embodiment of the present disclosure.

FIG. 7 is a cross-sectional view of a protection part and a COF film according to an embodiment of the present disclosure.

FIG. 8 is a view illustrating a protection part according to an embodiment of the present disclosure.

FIGS. 9A to 9C are plan views of a protection part including a plurality of patterns according to various embodiments of the present disclosure.

FIG. 10A to FIG. 10E is a view illustrating a display device in which a protection part is fastened according to various embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

The word “exemplary” is used to mean serving as an example or illustration. Aspects are merely examples described herein. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error band although there is no explicit description. Any implementation described herein as an “example” is not necessarily to be construed as preferred or advantageous over other implementations.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, one embodiment of the present disclosure will be described in detail with reference to the accompanying drawings.

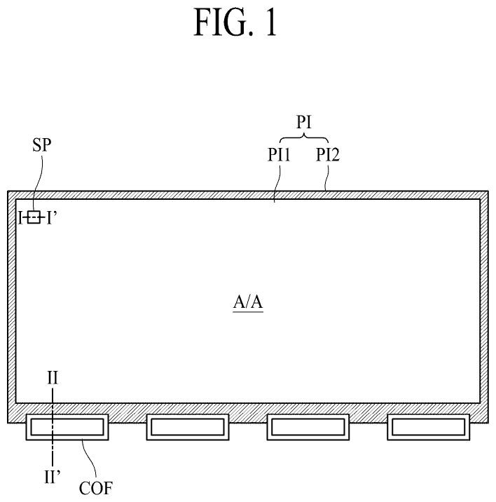

FIG. 1 is a plan view illustrating a display device according to an embodiment of the present disclosure.

Referring to FIG. 1, a display device of the present disclosure may include a flexible substrate PI. The flexible substrate PI may include a first substrate region PI1 and a second substrate region PI2 surrounding the first substrate region PI1. The first substrate region PI1 and the second substrate region PI2 are resin substrates having flexible characteristics and are formed of the same or different materials.

A display part A/A may be disposed on the first substrate region PI1, and the second substrate region PI2 may be disposed outside the display part A/A. A pad part may be disposed on one side of the second substrate region PI2. For example, the pad part may be disposed a lower side of the second substrate region PI2, but the present disclosure is not limited thereto. A COF film COF may be disposed in the pad part.

The display part A/A includes a plurality of sub-pixels SP, and may emit red, green, and blue light, or may emit red, green, blue, and white light. A GIP driver (not shown) for applying a gate driving signal to the display part A/A may be disposed at one side of the display unit A/A. Also, the COF film (Chip on Film) may be attached to the pad part (not shown) disposed at one side of the display part A/A. For example, the GIP driver may be disposed at a right side of the display part A/A, and the pad part may be disposed at the lower side of the display part A/A. Data signals and power may be applied to a plurality of signal lines (not shown) disposed in the display part A/A through the COF film (Chip on Film).

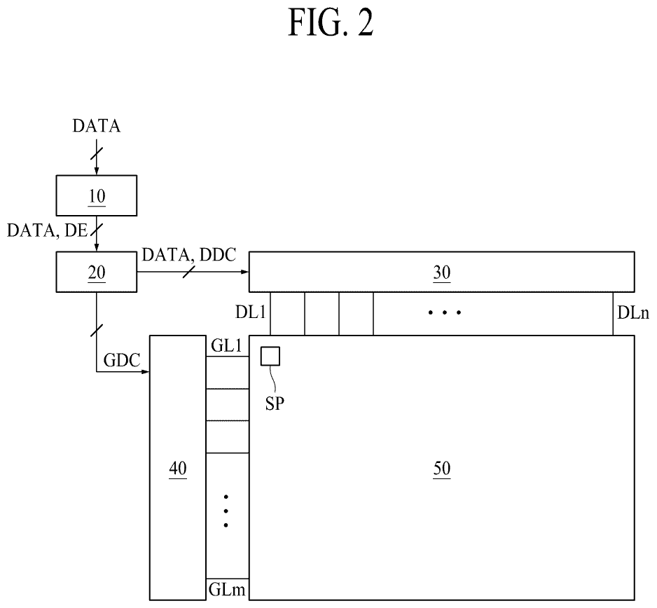

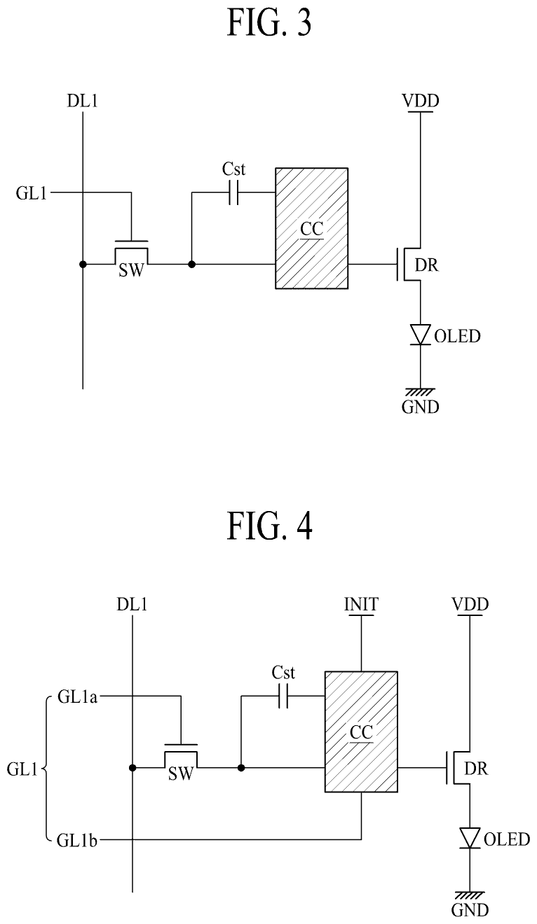

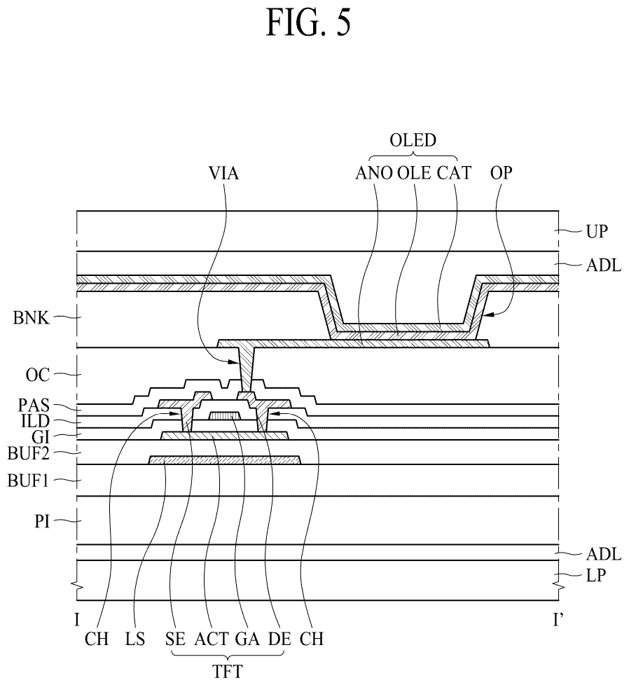

FIG. 2 is a block diagram of a display device according to an embodiment of the present disclosure. FIG. 3 is a circuit diagram illustrating a circuit configuration of a subpixel according to an embodiment of the present disclosure. FIG. 4 is a circuit diagram illustrating a circuit configuration of a subpixel according to another embodiment of the present disclosure.

Referring to FIG. 2, the display device may include an image processor 10, a timing controller 20, a data driver 30, a gate driver 40, and a display panel 50.

The image processor 10 may output a data signal DATA and a data enable signal DE supplied from the outside. The image processor 10 may output various driving signals in addition to the data enable signal DE. For example, the image processer 10 may output one or more of a vertical synchronization signal, a horizontal synchronization signal, and a clock signal, but is not limited thereto. Also, the image processor 10 may be formed in an integrated circuit (IC) form on a system circuit board.

The timing controller 20 may receive the data signal DATA and the data enable signal DE from the image processor 10. Also, the timing controller 20 may receive various driving signals such as a vertical synchronization signal, a horizontal synchronization signal, and a clock signal.

The timing controller 20 may output a gate timing control signal GDC and a data timing control signal DDC based on a driving signal. The gate timing control signal GDC may control an operation timing of the gate driver 40, and the data timing control signal DDC may control an operation timing of the data driver 30. Also, the timing controller 20 may be formed in an integrated circuit (IC) form on a control circuit board.

In response to the data timing control signal DDC supplied from the timing controller 20, the data driver 30 may convert the data signal DATA supplied from the timing controller 20 into a gamma reference voltage and output the gamma reference voltage. Also, the data driver 30 may output the data signal DATA through data lines DL1 to DLn. The data driver 30 may be attached to the substrate in the form of an IC.

In response to the gate timing control signal GDC supplied from the timing controller 20, the gate driver 40 may output a gate signal while shifting a level of a gate voltage. Also, the gate driver 40 may output the gate signal through gate lines GL1 to GLm. The gate driver 40 may be formed in an IC form on the gate circuit board or may be formed in a gate in panel (GIP) type on the display panel 50.

The display panel 50 may display an image corresponding to the data signal DATA and the gate signal supplied from the data driver 30 and the gate driver 40. Also, the display panel 50 may include sub-pixels SP for displaying an image.

Referring to FIG. 3, one sub-pixel SP may include a switching transistor SW, a driving transistor DR, a compensation circuit CC, and an organic light emitting diode OLED. According to a driving current formed by the driving transistor DR, the organic light emitting diode OLED may emit light.

As the switching transistor SW operates in response to the gate signal supplied from the gate line GL1, the data signal supplied from the first data line DL1 may be stored as a data voltage in a capacitor Cst. Also, as the driving transistor DR operates based on the data voltage stored in the capacitor Cst, a driving current may flow between a high-potential power line VDD and a low-potential power line GND.

The compensation circuit CC may compensate for a threshold voltage of the driving transistor DR. Also, the capacitor connected to the switching transistor SW or the driving transistor DR may be disposed in the compensation circuit CC. The compensation circuit CC may include one or more thin film transistors and capacitors. Since the configuration of the compensation circuit CC varies based on a compensation method, detailed examples and descriptions thereof will be omitted.

In addition, as shown in FIG. 4, when the compensation circuit CC is included, the sub-pixel may further include a signal line and a power line to drive a compensation thin film transistor or supply additional signals.

For example, the gate line GL1 may include a 1-1 gate line GL1a for supplying the gate signal to the switching transistor SW and a 1-2 gate line GL1b for driving the compensation thin film transistor included in the sub-pixel. An initialization power line INIT for initializing a specific node of the sub-pixel to a specific voltage may be further provided. However, this is only an example and is not limited thereto.

Meanwhile, FIGS. 3 and 4 show that the compensation circuit CC is included in one subpixel. However, when a circuit disposed outside the subpixel is compensated, the compensation circuit CC may be omitted. For example, when the operation of the data driver 30 is compensated, the compensation circuit CC may be omitted.

That is, one sub-pixel is basically configured as a 2T (Transistor) 1C (Capacitor) structure including a switching transistor SW, a driving transistor DR, a capacitor, and an organic light emitting diode OLED, but when the compensation circuit CC is added, the sub-pixel may be variously configured as 3T1C, 4T2C, 5T2C, 6T2C, 7T2C, etc. Furthermore, although FIG. 2 and FIG. 3 illustrate that the compensation circuit CC is disposed between the switching transistor SW and the driving transistor DR, the compensation circuit CC may also be disposed between the driving transistor DR and the organic light emitting diode OLED. The position and structure of the compensation circuit CC are not limited to FIGS. 3 and 4.

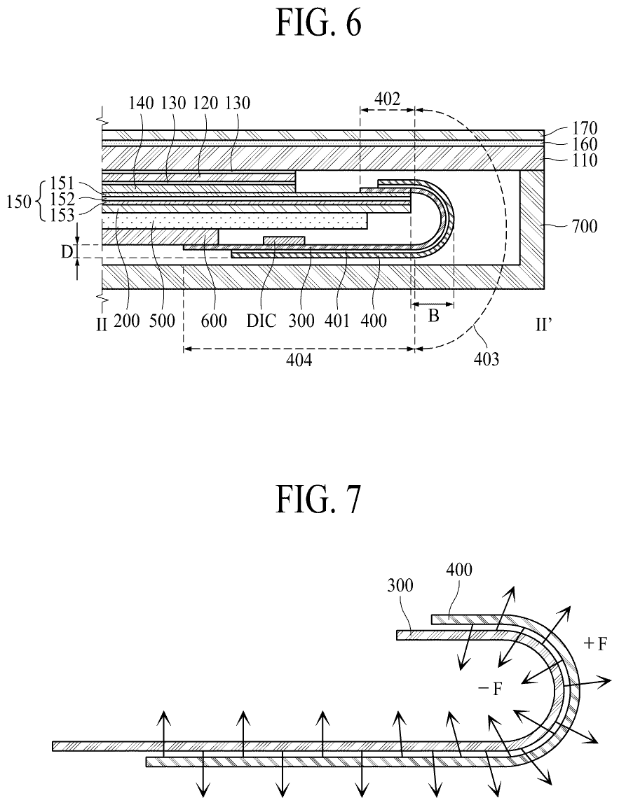

Hereinafter, a cross-sectional structure of a sub-pixel SP of the display device will be described with reference to FIG. 5 of the present invention.

Referring to FIG. 5, a display device according to an embodiment of the present disclosure may include a flexible substrate PI. The flexible substrate PI may have a flexible characteristic. For example, the flexible substrate PI may be a polyimide substrate.

A first buffer layer BUF1 may be disposed on the flexible substrate PI. The first buffer layer BUF1 may protect a thin film transistor formed in a subsequent process from impurities such as alkali ions flowing out of the flexible substrate PI. The first buffer layer BUF1 may be a single layer or multiple layers including silicon oxide (SiOx), silicon nitride (SiNx), or the like.

A shield layer LS may be disposed on the first buffer layer BUF1. When a polyimide substrate is used, a panel driving current may be reduced. In this case, the shield layer LS may prevent a decrease in panel driving current.

A second buffer layer BUF2 may be disposed on the shield layer LS. The second buffer layer BUF2 may protect a thin film transistor formed in a subsequent process from impurities such as alkali ions flowing out of the shield layer LS. The second buffer layer BUF2 may be a single layer or multiple layers including silicon oxide (SiOx), silicon nitride (SiNx), or the like.

A thin film transistor TFT may be disposed on the second buffer layer BUF2. The thin film transistor TFT may include a semiconductor layer ACT, a gate insulating layer GI, a gate electrode GA, a drain electrode DE, and a source electrode SE.

The semiconductor layer ACT may be disposed on the second buffer layer BUF2. The semiconductor layer ACT may be formed of a silicon semiconductor or an oxide semiconductor. The silicon semiconductor may include amorphous silicon or crystallized polycrystalline silicon. Also, the semiconductor layer ACT may include a drain region and a source region including p-type or n-type impurities and may include a channel disposed therebetween.

The gate insulating layer GI may be disposed on the semiconductor layer ACT. The gate insulating layer GI may be a single layer or multiple layers including silicon oxide (SiOx), silicon nitride (SiNx), or the like.

The gate electrode GA may be disposed on the gate insulating layer GI. Also, the gate electrode GA may be disposed at a position corresponding to the channel of the semiconductor layer ACT. The gate electrode GA may be a single layer or multiple layers including any one selected from a group consisting of molybdenum (Mo), aluminum (Al), chromium (Cr), gold (Au), titanium (Ti), nickel (Ni), neodymium (Nd), and copper (Cu). For example, the gate electrode GA may be a double layer including molybdenum and aluminum-neodymium or including molybdenum and aluminum.

An interlayer insulating layer ILD is disposed on the gate electrode GA, and may insulate the gate electrode GA. The interlayer insulating layer ILD may be a single layer or multiple layers including a silicon oxide layer (SiOx), a silicon nitride layer (SiNx) or the like. A contact hole CH exposing a portion of the semiconductor layer ACT may be formed in the interlayer insulating layer ILD and the gate insulating layer GI.

A drain electrode DE and a source electrode SE may be disposed on the interlayer insulating layer ILD. The drain electrode DE may be connected to the semiconductor layer ACT through the contact hole CH exposing the drain region of the semiconductor layer ACT. Also, the source electrode SE may be connected to the semiconductor layer ACT through the contact hole CH exposing the source region of the semiconductor layer ACT.

When the source electrode SE and the drain electrode DE are a single layer, the source electrode SE and the drain electrode DE may be a single layer or multiple layers including any one selected from a group consisting of molybdenum (Mo), aluminum (Al), chromium (Cr), gold (Au), titanium (Ti), nickel (Ni), neodymium (Nd), and copper (Cu). In addition, when the source electrode SE and the drain electrode DE are multiple layers, the source electrode SE and the drain electrode DE may be formed of a double layer of molybdenum/aluminum-neodymium, a triple layer of titanium/aluminum/titanium, molybdenum/aluminum/molybdenum or a triple layer of molybdenum/aluminum-neodymium/molybdenum.

A passivation layer PAS may be disposed on the thin film transistor TFT. The passivation layer PAS is an insulating layer protecting an element under the passivation layer and may be a single layer or multiple layers including a silicon oxide layer (SiOx), a silicon nitride layer (SiNx) or the like.

An overcoat layer OC may be disposed on the passivation layer PAS. The overcoat layer OC may be a planarization layer for compensating a step difference of a lower structure. Also, the overcoat layer OC may be formed of an organic material such as polyimide, benzo cyclobutene series resin, acrylate, and the like. A via hole VIA exposing the drain electrode DE may be formed in the overcoat layer OC.

An organic light emitting diode OLED may be disposed on the overcoat layer OC. The organic light emitting diode OLED may include a first electrode ANO, an organic layer EML, and a second electrode CAT.

The first electrode ANO may be disposed on the overcoat layer OC. The first electrode ANO functions as a pixel electrode and may be connected to the drain electrode DE of the thin film transistor TFT through the via hole VIA. The first electrode ANO may be formed of a transparent conductive material such as indium tin oxide (ITO), indium zinc oxide (IZO), or zinc oxide (ZnO). When the first electrode ANO is a reflective electrode, the first electrode ANO may further include a reflective layer. The reflective layer may be formed of aluminum (Al), copper (Cu), silver (Ag), nickel (Ni), or an alloy thereof, and preferably may be formed of APC (silver/palladium/copper alloy).

A bank BNK may be disposed on the first electrode ANO. The bank BNK may be formed of an organic material such as polyimide, benzo cyclobutene series resin, acrylate, and the like. Also, the bank BNK may include a pixel defining part OP exposing the first electrode ANO.

The organic layer OLE may be disposed on the first electrode ANO. Also, the organic layer OLE may be disposed on an entire surface of the display part A/A. The organic layer OLE may be a layer in which electrons and holes are coupled to emit light. Also, a hole injection layer or a hole transport layer may be disposed between the organic layer EML and the first electrode ANO, and an electron transport layer or an electron injection layer may be disposed on the organic layer OLE.

The second electrode CAT may be disposed on the organic layer OLE. Also, the second electrode CAT may be disposed on the entire surface of the display part A/A. The second electrode CAT may be formed of magnesium (Mg), calcium (Ca), aluminum (Al), silver (Ag), or an alloy thereof, which have low work functions. When the second electrode CAT is a transmissive electrode, the second electrode CAT may be formed to be thin enough to transmit light, and when the second electrode CAT is a reflective electrode, the second electrode CAT may be formed to be thick enough to reflect light.

An upper protection member UP may be disposed on the flexible substrate PI. The upper protection member UP may be attached onto the organic light emitting diode OLED through an adhesive layer ADL. The upper protection member UP may be a transparent flexible substrate or a metal thin film.

A lower protection member LP may be disposed under the flexible substrate PI. The lower protection member LP may be attached to a bottom surface of the flexible substrate PI through the adhesive layer ADL. Since light must be transmitted, the lower protection member LP may be formed of a transparent plastic film.

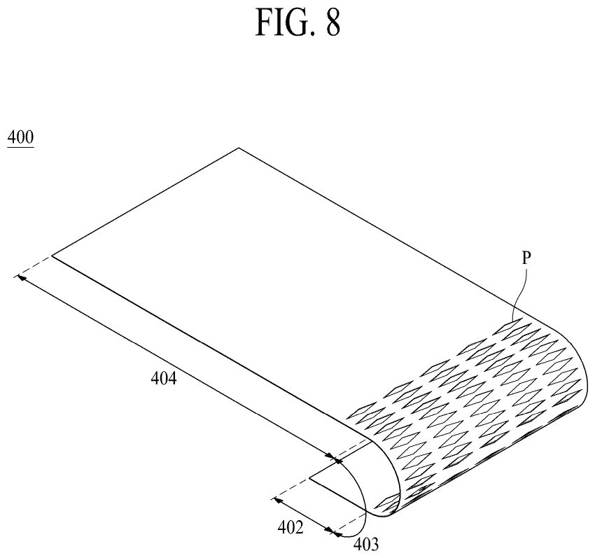

FIG. 6 is a cross-sectional view of a display device according to an embodiment of the present disclosure. Specifically, FIG. 6 is a cross-sectional view taken along a line II-II′ illustrated in FIG. 1, which is a display device according to an embodiment of the present disclosure.

Referring to FIG. 6, the display device 100 according to an embodiment of the present disclosure may include a cover glass 110, a viewing angle control film 120, an adhesive layer 130, a polarizing plate 140, an OLED panel 150, a back plate 200, a COF film 300, a protection part 400, a support member 500, and a printed circuit board 600.

The cover glass 110 is made of a hard material and may protect the OLED panel 150. For example, the cover glass 110 may be made of a glass material.

A protective film 160 may be disposed on an upper surface of the cover glass 110. Also, a touch panel 170 may be disposed on the cover glass 110. The touch panel may be a pressure-sensitive type that identifies a position where pressure is applied as a coordinate through a plurality of sensor lines responding to the pressure, or an electrostatic type that identifies a position where contact is made by detecting a degree of loss of electric charge during contact may be applied.

The OLED panel 150 outputs an image and may include a structure in which the above-described sub-pixels in FIG. 5 are arranged in a matrix form. Also, the OLED panel 150 may include a color filter substrate 151 and an array substrate 152 bonded to face each other to maintain a uniform gap.

The color filter substrate 151 may include a color filter composed of a plurality of sub-color filters implementing red, green, and blue, a black matrix separating the sub-color filters, and an overcoat layer formed on the color filter and the black matrix.

The array substrate 152 includes a plurality of gate lines and a plurality of data lines defining a pixel area and may include a thin film transistor (TFT) disposed in an intersection area of the plurality of gate lines and the plurality of data lines. The thin film transistor may include a gate electrode connected to the gate line, a source electrode connected to the data line, and a drain electrode connected to a pixel electrode.

The polarizing plate 140 and the viewing angle control film 120 may be disposed on the OLED panel 150. The polarizing plate 140 and the viewing angle control film 120 may control light in a specific direction to adjust the viewing angle.

The viewing angle control film 120 may be fixed by the adhesive layer 130 disposed on an upper surface and a lower surface of the viewing angle control film 120. The adhesive layer 130 may be formed of an optically clear resin (OCR) or an optically clear adhesive film (OCA film).

The back plate 200 may be disposed under the OLED panel 150. The back plate 200 may support the flexible substrate 153 of the OLED panel 150.

Specifically, in a process of manufacturing the organic light emitting diode, a support substrate may be disposed below the flexible substrate 153 of the OLED panel 150. After the process of manufacturing the organic light emitting diode is completed, the support substrate is separated from the flexible substrate 153 of the OLED panel 150. Accordingly, since a component for supporting the flexible substrate 153 is required, the back plate 200 may be disposed below the flexible substrate 153.

The back plate 200 may be formed of a plastic thin film made of polyimide, polyethylene naphthalate (PEN), polyethylene terephthalate (PET), polymers, or a combination thereof.

The support member 500 is disposed under the back plate 200 and may be attached to the back plate 200. The support member 500 may be made of a plastic material such as polycarbonate (PC), polyimide (PI), polyethylene naphthalate (PEN), polyethylene terephthalate (PET), polymers, a combination thereof, or the like. Alternatively, the support member 500 may include glass, ceramic, metal, or other rigid material. Further, in order to increase a thickness and a strength of the support member 500, various additives may be added to the support member 500. Therefore, the strength of the support member 500 may be controlled.

The COF film 300 (Chip on Film) is disposed on an end of the OLED panel 150 and may be electrically connected to the OLED panel 150. The COF film 300 may include various wirings for transmitting a signal to subpixels disposed on the display part A/A.

The COF film 300 may include polycarbonate, polyethylene terephthalate, polyimide, polyamide, polyester, polyacrylate, polymethyl methacrylate, and the like, but is not limited thereto. That is, the COF film 300 may be made of a flexible material and may be bent.

A driving element DIC may be mounted on the COF film 300. The driving element DIC may provide a driving signal and data to the subpixels disposed on the display part A/A. The driving element DIC may be disposed by a method such as a chip-on-glass, a chip-on-film, a tape carrier package, or the like, depending on a method of being mounted thereon. In the present disclosure, it is described that the driving element DIC is formed by the chip-on film method in which the driving element DIC is mounted on the COF film 300, but is not limited thereto. The driving element DIC may include a gate driver IC and a data driver IC.

The printed circuit board 600 may be electrically connected to the COF film 300. The printed circuit board 600 may receive image signals from the outside and apply various signals to subpixels disposed on the display part A/A.

The protection part 400 is disposed on the COF film 300 and may have a bent shape surrounding the COF film 300.

The protection part 400 may be fixed to the COF film 300 by an adhesive member 401. The adhesive member 401 may be disposed on a front surface of the protection part 400 or on a part of the protection part 400, but the present disclosure is not limited thereto. For example, when the adhesive member 401 is disposed on a part of the protection part 400, the adhesive member 401 may be positioned on a bending part of the COF film 300. The adhesive member 401 attached to the bending part may adhere the COF film 300 and the protection part 400, thereby improving a fixing force between the COF film 300 and the protection part 400.

One side of the COF film 300 may be connected to the OLED panel 150, and the other side of the COF film 300 may be connected to the printed circuit board 600. When the COF film 300 is bent while surrounding a side surface of the OLED panel 150, the printed circuit board 600 may be attached to a rear surface of the support member 500. In this case, the driving element DIC mounted on the COF film 300 may face the support member 500.

The protection part 400 may be disposed on one surface of the COF film 300, and the driving element DIC may be disposed on the other surface of the COF film 300. That is, the protection part 400 may be disposed on one surface of the COF film 300 on which the driving element DIC is not disposed. Also, the protection part 400 may be spaced apart from the printed circuit board 600 and may not overlap the printed circuit board 600. Accordingly, the protection part 400 may prevent problems such as cracks and tearing that occur when the COF film 300 is bent, and may safely protect the driving element DIC mounted on the COF film 300.

A set frame 700 may surround the OLED panel 150 and the COF film 300 and may protect all components.

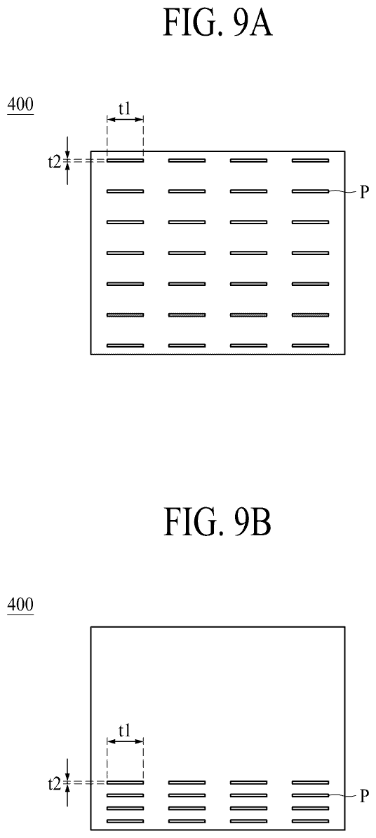

The protection part 400 according to an embodiment of the present disclosure will be described in more detail with reference to FIGS. 7 to 10.

FIG. 7 is a cross-sectional view of a protection part 400 and a COF film 300 according to an embodiment of the present disclosure. Referring to FIG. 7, the bent COF film 300 may have a restoring force (+F) to be unfolded again, and the protection part 400 may have a shape maintaining force (−F) to maintain a current shape. In this case, the restoring force (+F) of the COF film 300 and the shape maintaining force (−F) of the protection part 400 may achieve a balance of forces.

Accordingly, a stable structure may be maintained in a state in which the COF film 300 and the protection part 400 are attached to each other. Also, compared to a curvature of the COF film 300 when the COF film 300 is bent alone, a curvature of the COF film 300 when the COF film 300 surrounding by the protection part 400 is bent may be smaller.

Furthermore, since the COF film 300 and the protection part 400 are in close contact with each other without being separated, it is possible to prevent or at least reduce the occurrence of cracks, tearing, and pattern breaking that may occur at an outer wall of the COF film 300 due to bending of the COF film 300. Accordingly, it is possible to prevent the occurrence of a defect in the display device 100.

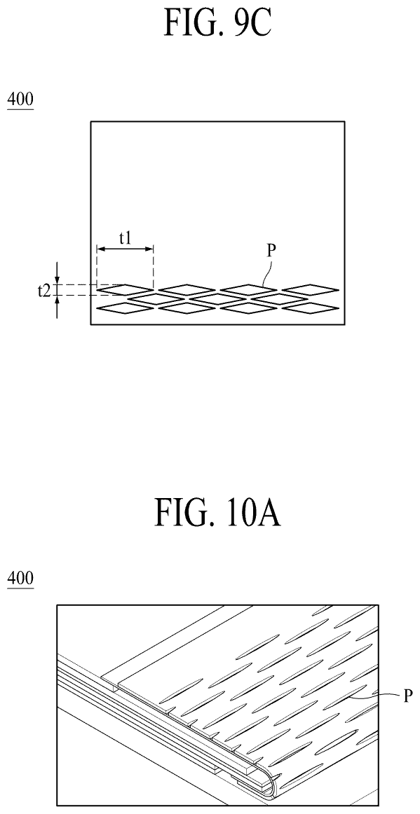

FIG. 8 is a view illustrating a protection part according to an embodiment of the present disclosure. Referring to FIG. 8, as an elongation of the protection part 400 is increased, when the protection part 400 is attached to the COF film 300, bending of the protection part 400 may be performed smoothly. However, as the elongation of the protection part 400 is increased, a strength of the shape maintaining force of the protection part 400 may be decreased. Accordingly, it may be difficult to fix a shape of the protection part 400.

Therefore, it may be desirable to use a plastic material having the elongation of 25% to 45%. For example, the protection part 400 may be made of a plastic material such as polycarbonate (PC), polyimide (PI), polyethylene naphthalate (PEN), polyethylene terephthalate (PET), polymers, combinations thereof, and the like.

Alternatively, the protection part 400 may be formed of a metal material. For example, the protection part 400 may be formed of aluminum. Since aluminum has an excellent conduction effect, heat dissipation effect may be improved by reducing heat generated from the printed circuit board 600 when driving the display device 100.

In one embodiment, a thickness of the protection part 400 may be 0.15 mm or less so that the protection part 400 may not be damaged while maintaining the curvature as much as possible. Also, the thickness of the protection part 400 may be 0.1 mm or more so as to have rigidity capable of maintaining a shape of the COF film 300 when the COF film 300 is bent.

The protection part 400 may include a first region 402, a bending part 403, and a second region 404. The bending part 403 may be disposed between the first region 402 and the second region 404. Also, the first region 402 may be parallel to the second region 404. Accordingly, interference between the COF film 300 and the set frame 700 may be minimized, and a narrow bezel and a slimming structure of the display device 100 may be possible.

One surface of the second region 404 of the protection part 400 may be parallel to the support member 500. That is, a region not bent in the COF film 300 may be parallel to the support member 500. Accordingly, bending or wrinkles unnecessarily occurring in the COF film 300 may be prevented, and a length of use of the COF film 300 may be shortened, thereby facilitating cost reduction.

As described above, since it is not necessary to consider a sagging area of the COF film 300 by the protection part 400, a length B from an end of the OLED panel 150 to an end of the bending part 403 of the protection part 400 may be minimized or at least reduced. Accordingly, when the set frame 700 is mounted, an entire bezel of the display device 100 may be reduced.

A boundary area between the first region 402 and the bending part 403 of the protection part 400, and a boundary area between the second region 404 and the bending part 403 may be disposed outside an end of the OLED panel 150. That is, the bending part 403 may not be in contact with the upper surface and the lower surface of the OLED panel 150. Therefore, it is possible to prevent the end of the OLED panel 150 from being damaged by the bending part 403.

Also, since the COF film 300 may reduce curvature when bent together with the protection part 400 than when the COF film 300 is bent in a single configuration. Therefore, a distance D from a bottom surface of the printed circuit board 600 to a bottom surface of the second region 404 of the protection part 400 may be minimized. Accordingly, a total thickness of the display device 100 may be reduced when the set frame 700 is mounted.

Since the COF film 300 is fixed by the protection part 400, damage to the COF film 300 due to component shaking may be prevented. In this case, an area of the protection part 400 may be smaller than an area of the COF film 300. Since the bending part of the COF film 300 is an area in which damage to the COF film 300 due to bending most easily occurs, the protection part 400 may also be located only at the bending part of the COF film 300. Accordingly, the protection part 400 may protect the COF film 300 from an external environment and may smoothly support the bending part of the COF film 300 without bending or sagging.

Furthermore, a plurality of patterns P may be formed in the protection part 400. The plurality of patterns P include a plurality of holes, and thus the protection part 400 may be smoothly bent.

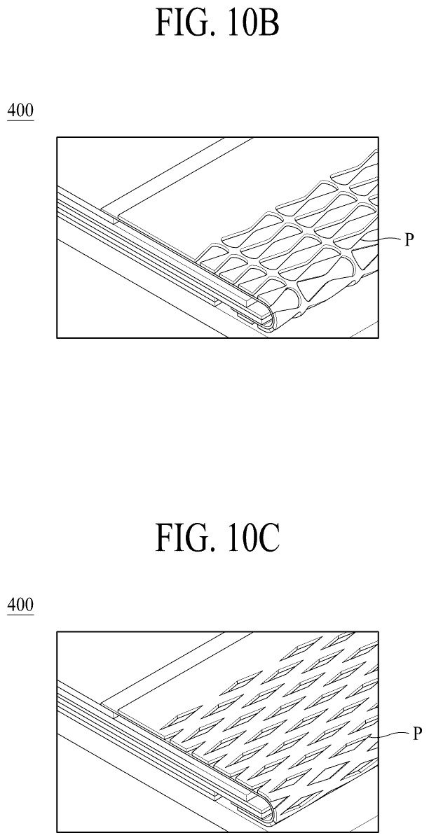

FIGS. 9A to 9C are plan views of a protection part including a plurality of patterns according to various embodiments of the present disclosure. Referring to FIGS. 9A to 9C, the plurality of patterns P positioned in the protection part 400 may be arranged in various forms. The plurality of patterns P may be positioned at regular intervals on an entire surface of the protection part 400 or may be positioned at regular intervals in a partial area of the protection part 400. In this case, the partial area of the protection part 400 may be the first region 402 and the bending part 403, but is not limited thereto.

The plurality of patterns P of the protection part 400 may be formed in a circular, rectangular, trapezoidal, or diamond shape, but the present disclosure is not limited thereto. A length of a short axis t2 of the plurality of patterns P of the protection part 400 may be 8% or less of a length of a long axis t1. The protection part 400 may be bent at the same curvature as the curvature of the COF film 300 to prevent a risk of damage.

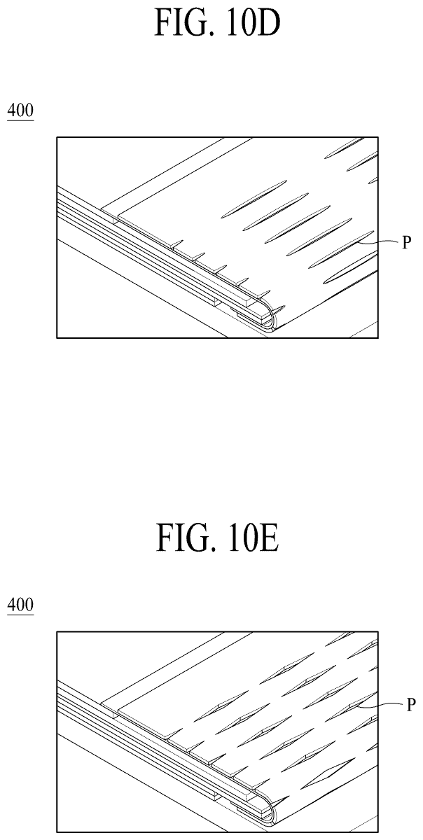

FIG. 10A to FIG. 10E is a view illustrating a display device in which a protection part is fastened according to various embodiments of the present disclosure. Referring to FIGS. 10A to 10E, it may be seen that the protection part 400 including the plurality of various patterns P is coupled to the display panel.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a display panel;
a backplate supporting the display panel;
a support member supporting the backplate;
a chip on film (COF) film that is electrically connected to the display panel and having a bent shape;
a protection part surrounding the COF film, the protection part having a bent shape; and
an adhesive member between the COF film and the protection part,
wherein one side of the COF film is connected to the display panel and another side of the COF film is disposed on a rear surface of the support member.

2. The display device of claim 1, further comprising:
a driving element mounted on the COF film and facing the support member; and
a printed circuit board electrically connected to the COF film above.

3. The display device of claim 2, wherein the driving element is disposed on one surface of the COF film,
the protection part is disposed on another surface of the COF film on which the driving element is not mounted, and
the protection part is spaced apart from the printed circuit board.

4. The display device of claim 1, further comprising:
a polarizing plate disposed on the display panel;
a viewing angle control film disposed on the polarizing plate; and
a cover glass disposed on the viewing angle control film.

5. The display device of claim 1, further comprising:
a set frame surrounding the display panel and the COF film.

6. The display device of claim 1, wherein one surface of the COF film is horizontal with the support member.

7. The display device of claim 1, wherein the protection part includes a metal with an elongation in a range of 25% to 45%.

8. The display device of claim 1, wherein a thickness of the protection part is 0.15 mm or less.

9. The display device of claim 1, wherein an entire first surface of the adhesive member is in contact with the protection part and an entire second surface of the adhesive member is in contact with the COF film.

10. The display device of claim 1, wherein an area of the protection part is smaller than an area of the COF film.

11. The display device of claim 1, wherein the protection part includes:
a first region disposed on an upper portion of the display panel;
a second region disposed under the display panel; and
a bending part disposed between the first region and the second region,
wherein the first region and the second region are parallel to each other.

12. The display device of claim 1, wherein the COF film maintains a bent state by the protection part.

13. The display device of claim 1, wherein the protection part includes a plurality of patterns.

14. The display device of claim 13, wherein the plurality of patterns are disposed at equal intervals and are disposed in an entirety of the protection part.

15. The display device of claim 13, wherein the plurality of patterns are disposed at equal intervals and are disposed in a portion of the protection part.

16. The display device of claim 13, wherein the plurality of patterns have any one of a circular shape, a square shape, a trapezoid shape, or a diamond shape.

17. The display device of claim 13, wherein a length of a short axis of each of the plurality of patterns is 8% or less of a length of a long axis of each of the plurality of patterns.
